(19) United States
(12) Patent Application Publication
(10) Pub. No.: US 2008/0121925 A1
(43) Pub. Date: May 29, 2008

(54) LOW VOLTAGE TRIGGERED SILICON CONTROLLED RECTIFIER

(76) Inventor: Kook Whee KWAK, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/770,918

(22) Filed: Jun. 29, 2007

(30) Foreign Application Priority Data
Jun. 30, 2006 (KR) 10-2006-0061572

(51) Int. Cl. H01L 29/74

(52) U.S. Cl. 257/173; 257/E29.218

(57) ABSTRACT

Disclosed is a low voltage triggered silicon controlled rectifier (LVTSCR) . The LVTSCR includes a first-type semiconductor substrate; a second-type well formed in a predetermined region of the semiconductor substrate; first to third diffusion regions sequentially formed in the well; fourth to sixth diffusion regions sequentially formed at an outside of the well to be adjacent to the third diffusion resion; and a capacitor having one terminal connected to the third diffusion region and the other terminal connected to the fourth diffusion region.

### CROSS-REFERENCE TO RELATED APPLICATIONS

The present application claims priority to Korean patent application number 10-2006-0061572 filed on Jun. 30, 2006, which is incorporated herein by reference in its entirety.

### BACKGROUND OF THE INVENTION

The present invention relates to a semiconductor device, and more particularly to a low voltage triggered silicon controlled rectifier (hereinafter, referred to as an “LVTSCR”).

In general, a semiconductor device includes a static electricity discharge circuit between an input/output pad and an internal circuit so as to protect the internal circuit from being damaged due to an electrostatic discharge (ESD) current. A diode, a metal oxide silicon (MOS) transistor, and an LVTSCR are widely used as a static electricity discharge circuit for a semiconductor circuit.

A diode is capable of carrying a high ESD current per unit area of the anode-cathode junction and has a small junction capacitance, however, a diode has a relatively large dynamic resistance, and limitations remain in the independent use of the diode.

A metal oxide semiconductor or MOS transistor has a low triggervoltage and can have a relatively low dynamic resistance, however, when used as an ESD device, a MOS transistor's current carrying capability is ⅓ to ⅕ lower than a diode or LVTSCR. Therefore, a MOS transistor should have a relatively large junction area in order for a MOS transistor to satisfy a certain level of the ESD current, but which will also increase junction capacitance.

Unlike diodes and MOS transistors, the LVTSCR has a higher ESD current capability per unit area, a smaller junction capacitance, and a lower dynamic resistance than the diodes or MOS transistors. However, the LVTSCR requires a higher triggervoltage than a MOS transistor and operates in a more unstable manner when ESD is generated than a MOS transistor, it is difficult to use a LVTSCR in a high-speed and low-voltage circuit.

The operation, advantages and disadvanatages of the aforementioned LVTSCR will be described with reference to FIGS. 1 and 2.

FIG. 1 is a sectional view showing the structure of a conventional LVTSCR, and FIG. 2 is an equivalent circuit diagram corresponding to FIG. 1.

The structure of the LVTSCR of FIG. 1 has been proposed by A. Chatterjee and T. polgreen, “A LVTSCR for On-Chip ESD Protection at Output and Input Pads”, IEEE Electron Devices Letters, vol. 12, pp. 21-22 (1991). The structure of the LVTSCR is a structure that has been most widely cited so far.

The LVTSCR has a PNPN structure including a P-type impurity diffusion region 132 corresponding to an anode 160, an N-type well 120, a P-type substrate 110, and an N-type impurity diffusion region 138 corresponding to a cathode 170. When the LVTSCR is used in an ESD protection circuit, an input/output pad (not shown) or VCC pad (not shown) is connected to the anode 160, and a VSS pad (not shown) or input/output pad (not shown) is connected to the cathode 170.

When an ESD is generated between the anode 160 and the cathode 170, an ESD voltage applied to the anode 160 rapidly increases, and the voltages of the N-type well 120 directly connected to the anode 160 and the N-type impurity diffusion region 134 simultaneously increase. Therefore, a strong reverse voltage is applied to an NP junction such as between the N-type impurity diffusion region 134 and the P-type substrate 110.

When the ESD voltage exceeds an avalanche breakdown voltage of the NP junction, a junction breakdown is generated. Then, an ESD current flows into the P-type substrate 110 via the N-type well 120 and then discharged to the cathode 170 via a P-type impurity diffusion region 140.

When the ESD current is discharged to the cathode 170 via the P-type impurity diffusion region 140, a substrate voltage around the N-type impurity diffusion region 138 is increased due to a substrate resistor Rsub. When the substrate voltage exceeds the forward operation voltage (about 0.7V) of a PN junction including the P-type substrate 110 and the N-type impurity diffusion region 138, the ESD current is discharged to the cathode 170 via the N-type impurity diffusion region 138. Accordingly, the operation of a parasitic NPN bipolar transistor T1 formed by the N-type well 120, the P-type substrate 110, and the N-type impurity diffusion region 138 is triggered to turn on to conduct current.

Through the operation of the parasitic NPN bipolar transistor T1, a current flowing from an N-type impurity diffusion region 130 to the cathode 170 via the parasitic NPN bipolar transistor T1 increases the well voltage of the N-type well 120 due to a well resistor Rnwell thereof. The well voltage of the N-type well 120 has a potential difference from the voltage of the P-type impurity diffusion region 132 that is an emitter E of a parasitic PNP bipolar transistor T2, thereby triggering the parasitic PNP bipolar transistor T2 to conduct current.

That is, since a collector C of the parasitic NPN bipolar transistor T1 corresponds to the base B of the parasitic PNP bipolar transistor T2, a current flowing through the parasitic NPN bipolar transistor T1 is also applied to the base B of the parasitic PNP bipolar transistor T2, thereby triggering the operation of the parasitic PNP bipolar transistor T2.

Thereafter, in the parasitic NPN and PNP bipolar transistors T1 and T2 having collectors and bases connected to each other, the operation of one of the two transistors causes operation of the other transistor. For this reason, the LVTSCR performs a high-efficiency ESD operation such that dynamic resistance is low, and a large ESD current can be conducted even in a small area.

However, since the operation of the LVTSCR depends on the avalanche breakdown voltage and current of an NP junction, the resistor Rnwell of an N-type well, the substrate resistor Rsub and the like, there is no appropriate method for controlling them. Since the conventional LVTSCR has a higher triggering voltage and its operational characteristics are considered to be relatviely unstable compared to a parasitic bipolar transistor of the MOS device, it is difficult to use a LVTSCR in a high-speed and low-voltage circuit.

### SUMMARY OF THE INVENTION

The present invention provides, inter alia, an LVTSCR having a high current conduction efficiency per unit area and a low triggering voltage, so that the operational stability of a low-voltage circuit can be enhanced.

The present invention also provides, inter alia, an LVTSCR capable of adjusting a triggering voltage to be suitable for products.

Futher yet, the present invention provides, inter alia, an LVTSCR having a high current conduction efficiency per unit area, a low triggering voltage and a high operational stability as an ESD protection element, so that an internal circuit can be protected from an electrostatic current.

According to an aspect of the present invention, there is provided an LVTSCR. The LVTSCR includes a first-type semiconductor substrate; a second-type well formed in a predetermined region of the semiconductor substrate; first to third diffusion regions sequentially formed in the well; fourth to sixth diffusion regions sequentially formed at an outside of the well to be adjacent to the third diffusion resion; and a capacitor having one terminal connected to the third diffusion region and the other terminal connected to the fourth diffusion region.

Preferably, the first-type semiconductor substrate and the second, fourth and sixth diffusion regions are doped with P-type impurities, and the second-type well and the first, third and fifth diffusion regions are doped with N-type impurities.

Preferably, the third diffusion region is formed to be included in both the well and the substrate such the third diffusion region crosses the boundary between the well and the substrate.

Preferably, the first and second diffusion region are connected to a power source terminal, and the fifth and sixth diffusion regions are connected to a ground terminal; the first and second diffusion regions are connected to an input/output pad, and the fifth and sixth diffusion regions are connected to a ground terminal; or the first and second diffusion regions are connected to a power source terminal, and the fifth and sixth diffusion regions are connected to an input/output pad.

The LVTSCR may further include a first resistor having one terminal connected to the first diffusion region and the other terminal connected to the second diffusion region; and a second resistor having one terminal connected to the fifth diffusion region and the other terminal connected to the sixth diffusion region.

### BRIEF DESCRIPTION OF THE DRAWINGS

FIG. 1 is a cross-sectional view showing the structure of a conventional LVTSCR.

FIG. 2 depicts an equivalent circuit diagram of the LVTSCR shown in FIG. 1.

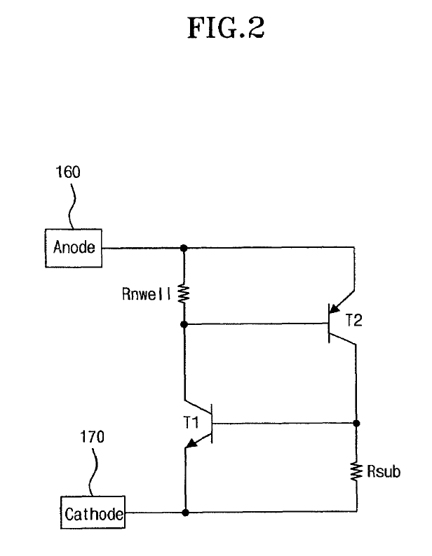

FIG. 3 is a cross-sectional view showing the structure of an LVTSCR according to a first embodiment of the present invention.

FIG. 4 is an equivalent circuit diagram corresponding to FIG. 3.

FIG. 5 is a cross-sectional view showing the structure of an LVTSCR according to a second embodiment of the present invention.

FIG. 6 is an equivalent circuit diagram corresponding to FIG. 5.

FIG. 7 is a graph comparing triggering voltages and currents in LVTSCRs of FIGS. 1 and 5 through simulation.

### DESCRIPTION OF SPECIFIC EMBODIMENTS

Hereinafter, a preferred embodiment of the present invention will be described in detail with reference to the accompanying drawings.

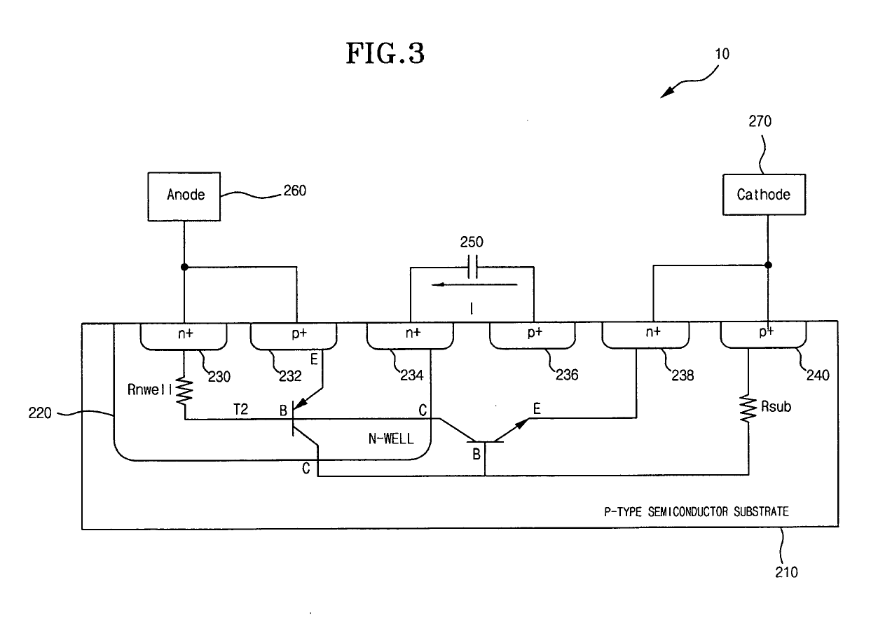

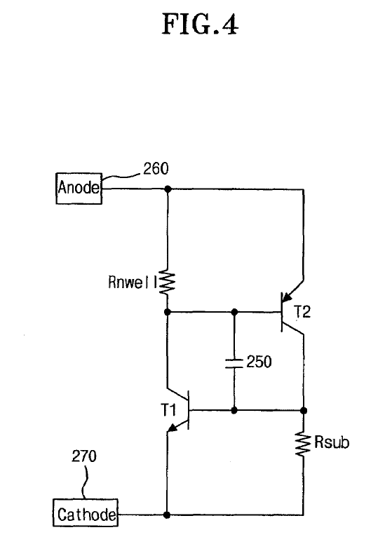

FIG. 3 is a cross-sectional view showing the structure of an LVTSCR 10 according to a first embodiment of the present invention. FIG. 4 is an equivalent circuit diagram of the LVTSCR device shown in FIG. 3.

Referring to FIGS. 3 and 4, the LVTSCR 10 according to the first embodiment includes an N-type well 220 formed in a predetermined region of a P-type substrate 210; a first N-type impurity diffusion region 230, a second P-type impurity diffusion region 232 and a third N-type impurity diffusion region 234, sequentially formed in the N-type well 220; and a fourth P-type impurity diffusion region 236, a fifth N-type impurity diffusion region 238 and a sixth P-type impurity region 240, sequentially formed to be adjacent to the third diffusion region 234 at the outside of the N-type well 220. The third diffusion region 234 is formed to be included in the N-type well 220 or formed to be included in both the N-type well 220 and the P-type substrate 230 crossing the boundary between the N-type well 220 and the P-type substrate 210 as shown in FIG. 3. The first and second diffusion regions 230 and 232 are connected to an anode 260, and the fifth and sixth diffusion regions 238 and 240 are connected to a cathode 270.

As described above, the LVTSCR 10 according to the first embodiment has a PNPN structure comprised of the second P-type impurity diffusion region 232 corresponding to the anode 260, the N-type well 220, the P-type substrate 210 and the fifth N-type impuritiy diffusion region 238 corresponding to the cathode 270.

When the LVTSCR 10 is used in an ESD protection circuit, an input/output pad (not shown) or VCC pad (not shown) is connected to the anode 260, and a VSS pad or input/output pad is connected to the cathode 270.

In the LVTSCR 10 of the first embodiment , the third diffusion region 234 is connected to the P-type substrate 210 through a capacitor 250 such that the dynamic voltage required for operating the LVTSCR 10 does not depend on the avalanche breakdown voltage of an NP junction including the third N-type impurity diffusion region 234 and the P-type substrate 210. That is, the third diffusion region 234 and the fourth diffusion region 236 adjacent thereto are electrically connected to each other through the external capacitor 250.

When an ESD is generated between the anode 260 and the cathode 270, an electrostatic current has a relatively fast signal rise time of approximately 10⁻⁹ second or so. An AC current I flows through the capacitor 250 due to the fast rise time characteristic (up to GHz) of an electrostatic voltage.

The AC current, I, generates a voltage drop corresponding to I*Rnwell, measured between the second diffusion region 232, which is an emitter of the parasitic PNP bipolar transistor T2 and the N-type well 220 that is a base thereof due to a resistor Rnwell of the N-type well 220, thereby rapidly triggering the operation of the parasitic PNP bipolar transistor T2.

The AC current, I, generates a voltage drop corresponding to I*Rsub between the fifth diffusion region 238 that is an emitter of the parasitic NPN bipolar transistor T1 and the P-type substrate 210 that is a base thereof due to a resistor Rsub of the P-type substrate 210, thereby rapidly triggering the operation of the parasitic NPN bipolar transistor T1.

In the parasitic NPN and PNP bipolar transistors T1 and T2 described above, which have the NPN collector connected to the PNP base, operation of one of the two transistors mutually causes operation of the other. Therefore, the LVTSCR 10 of FIG. 3 becomes a high-efficiency ESD operation such that its dynamic resistance is low, and large ESD current can be conducted even in a small junction area.

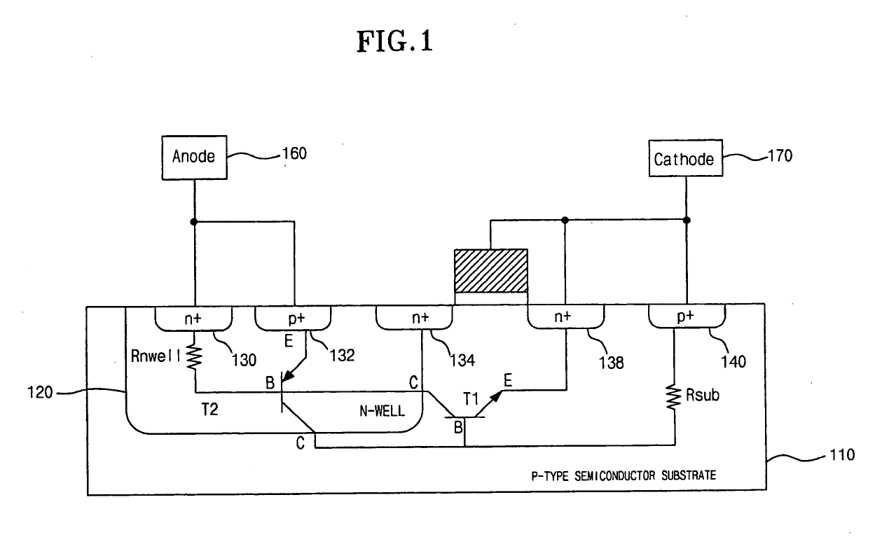

Unlike the LVTSCR of FIG. 3, the LVTSCR of FIG. 1 is operated when a dynamic voltage reaches an avalanche breakdown voltage of the NP junction including the third N-type impurity diffusion region 134 and the P-type substrate 110. In the LVTSCR 10 of FIG. 3, the parasitic PNP and NPN bipolar transistors T1 and T2 are rapidly turned on, corresponding to a voltage drop due to an initial ESD AC current induced by the capacitor 250, so that the operation of the LVTSCR can be performed at a voltage much lower that the conventional LVTSCR.

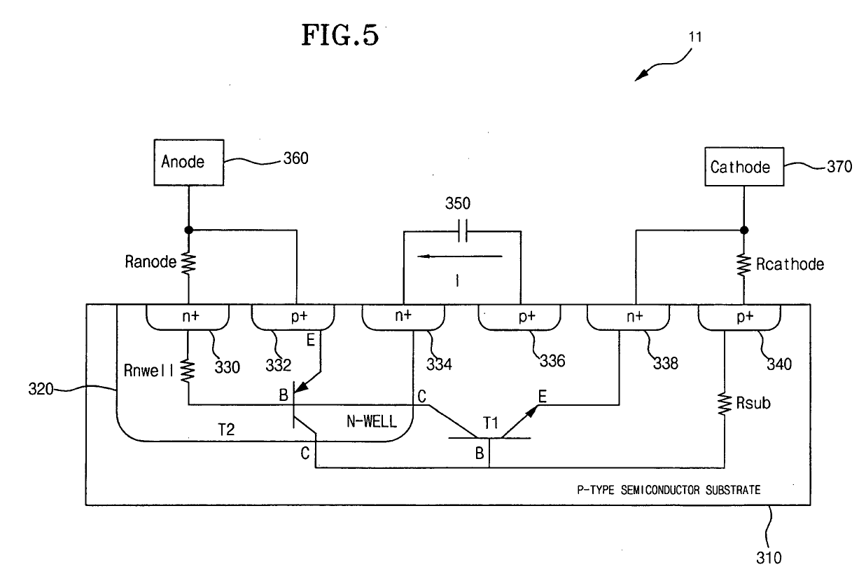

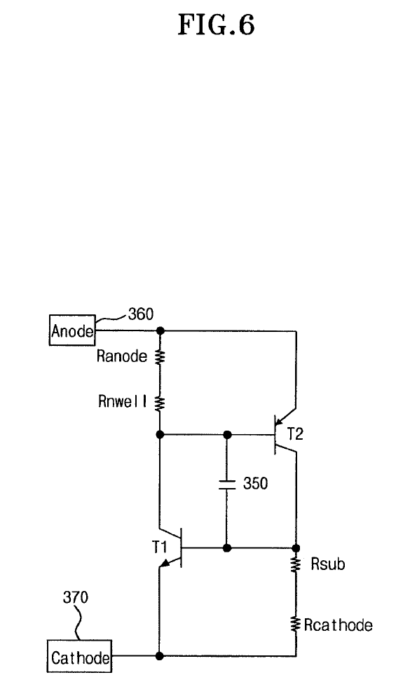

FIG. 5 is a sectional view showing the structure of an LVTSCR 11 according to a second embodiment of the present invention, and FIG. 6 is an equivalent circuit diagram corresponding to FIG. 5.

Referring to FIGS. 5 and 6, the LVTSCR 11 includes an N-type well 320 formed in a predetermined region of a P-type substrate 310; a first N-type impurity diffusion region 330, a second P-type impurity diffusion region 332 and a third N-type impurity diffusion region 334, sequentially formed in the N-type well 320; and a fourth P-type impurity diffusion region 336, a fifth N-type impurity diffusion region 338 and a sixth P-type impurity region 340, sequentially formed to be adjacent to the third diffusion region 334 at the outside of the N-type well 320.

The third diffusion region 334 is formed to be included in the N-type well 320 or formed to be included in both the N-type well 220 and the P-type substate 230 crossing the boundary between the N-type well 320 and the P-type substrate 310. The third diffusion region 334 and the fourth diffusion region 336 adjacent thereto are electrically connected to each other through a capacitor 350.

The first diffusion region 330 is connected to the second diffusion region 332 through a first resistor Ranode having a predetermined resistance, and the sixth diffusion region 340 is connected to the fifth diffusion region 338 through a second resistor Rcathode having a predetermined resistance.

As described above, the LVTSCR 11 of the second embodiment has a PNPN structure including the second P-type impurity diffusion region 332 corresponding to an anode 360, the N-type well 320, the P-type substrate 310 and the fifth N-type impuritiy diffusion region 338 corresponding to a cathode 370.

When the LVTSCR is used in an ESD protection circuit, an input/output pad or VCC pad (not shown) is connected to the anode 360, and a VSS pad or input/output pad (not shown) is connected to the cathode 370.

When an ESD is generated between the anode 360 and the cathode 370, an electrostatic current can have a fast signal rising time of 10⁻⁹ second or so. For this reason, an AC current I flows through the capacitor 350 due to the fast rising time characteristic (up to GHz) of an electrostatic voltage.

The AC current I causes a voltage drop corresponding to I*(Rnwell+Ranode) between the second diffusion region 332, which is an emitter of the parasitic PNP bipolar transistor T2 and the N-type well 320 that is a base thereof due to a resistor Rnwell of the N-type well 320 and the first resistor Ranode, thereby rapidly triggering the operation of the parasitic PNP bipolar transistor T2.

Moreover, the AC current I generates a voltage drop corresponding to I*(Rsub+Rcathode) between the fifth diffusion region 338 that is an emitter of the parasitic NPN bipolar transistor T1 and the P-type substrate 310 that is a base thereof due to a substrate resistor Rsub and the second resistor Rcathode, thereby rapidly triggering the operation of the parasitic NPN bipolar transistor T1.

Thereafter, in the parasitic NPN and PNP bipolar transistors T1 and T2 having the NPN transistor's collector connected to the PNP transistor's base, operation of one of the two transistors mutually causes or affects operation of the other transistor. Therefore, the LVTSCR 11 of FIG. 5 performs a high-efficiency ESD operation such that dynamic resistance is low, and a large ESD current can be conducted even in a small area.

As such, in the LVTSCR 11 according to the second embodiment, a voltage drop between the anode 360 and the cathode 370 due to an initial ESD AC current induced by the capacitor 350 is increased by the first and second resistors Ranode and Rcathode, so that the operation of the LVTSCR can be performed at a voltage lower than the LVTSCR according to the first embodiment.

In the conventional LVTSCR shown in FIG. 1, a dynamic voltage depends on the resistor Rnwell of the N-type well and the substrate resistor Rsub, so that the amplitude of the dynamic voltage cannot be adjusted. Unlike the prior art LVTSCR, the LVTSCR shown in FIG. 3 or FIG. 5 (either the first or second emodiment of the present invention) includes a capacitor capable of temporarily adjusting the amplitude of a voltage and the first and second resistors Ranode and Rcathode, as well as the the resistor Rnwell of the N-type well, so that the dynamic voltage of the LVTSCR can be controlled.

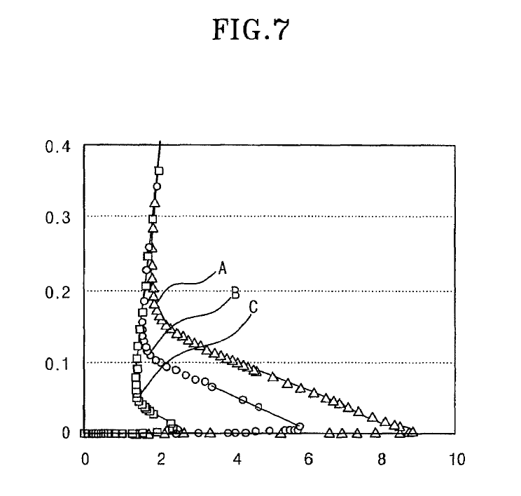

FIG. 7 is a graph comparing current-voltage characteristics in the LVTSCRs of FIGS. 1 and 5 through technology CAD (TCAD) simulation. Graph A represents a current-voltage characteristic of the conventional LVTSCR (FIG. 1), and graphs B and C represent current-voltage characteristics of the LVTSCR (FIG. 5) according to the second embodiment of the present invention, depending on the value of RC.

Here, the value of the RC denotes a value obtained by allowing the first and second resistors Ranode and Rcathode to be equal to each other and amplifying the first resistor Ranode by the capacitance.

Referring to FIG. 7, the triggering voltage of graph A is 8V or more, the triggering voltage of graph B is 6V or less, and the triggering voltage of graph C is 3V or less.

In the aforementioned results, the LVTSCR according to the present invention has a triggering voltage much lower than the conventional LVTSCR. In the present invention, a dynamic voltage becomes lower as the resistances of the first and second resistors Ranode and Rcathode become larger, i.e., as the value of the RC becomes larger. Accordingly, a triggering voltage can be adjusted to be suitable for products by using the value of the RC.

TABLE 1

| | | | Current conduction |
|---|---|---|---|
| | Operating | Holding | efficiency per anode |
| LVTSCR structure | voltage | voltage | area (mA/μm²) |
| LVTSCR of FIG. 1 | 8.9 | 1.8 | 43.5 |
| LVTSCR of FIG. 5 | 2.4 | 1.4 | 43.8 |

Table 1 is a table comparing triggering voltages and maximum current capable of being conducted per unit area in the LVTSCRs of FIGS. 1 and 5.

Referring to Table 1, the triggering voltage of the LVTSCR of the present invention is 2.4V, much lower than that of the conventional LVTSCR, i.e., 8.9V. Further, the current efficiency of the LVTSCR of the present invention is 43.8 mA /μm² similar to that of the conventional LVTSCR, i.e., 43.5 mA/μm². Accordingly, the LVTSCR of the present invention has superior characteristics.

According to the present invention, there is provide an LVTSCR having a high current conduction efficiency per unit area and a low triggering voltage, so that the operational stability of a low-voltage circuit can be enhanced.

Further, there is provided an LVTSCR capable of adjusting a triggering voltage to be suitable for products.

Furthermore, an LVTSCR having a high current conduction efficiency per junction unit area, a low triggering voltage and a high operational stability is provided as an ESD protection element, so that an internal circuit can be protected from an electrostatic current.

Those skilled in the art will appreciate that the specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the invention as set forth in the appended claims.

What is claimed is:

1. A low voltage triggered silicon controlled rectifier (LVTSCR), comprising:
a first-type semiconductor substrate;
a second-type well formed in a predetermined region of the semiconductor substrate;
first, second, and third diffusion regions sequentially formed in the well;
fourth, fifth, and sixth diffusion regions sequentially formed in the substrate outside the well and adjacent to the third diffusion resion; and
a capacitor having a first terminal connected to the third diffusion region and a second terminal connected to the fourth diffusion region.

2. The LVTSCR as set forth in claim 1, wherein the first-type semiconductor substrate and the second, fourth and sixth diffusion regions are doped with P-type impurities, and the second-type well and the first, third and fifth diffusion regions are doped with N-type impurities.

3. The LVTSCR as set forth in claim 1, wherein the first and second diffusion region are connected to a power source terminal, and the fifth and sixth diffusion regions are connected to a ground terminal.

4. The LVTSCR as set forth in claim 1, wherein the first and second diffusion regions are connected to an input/output pad, and the fifth and sixth diffusion regions are connected to a ground terminal.

5. The LVTSCR as set forth in claim 1, wherein the first and second diffusion regions are connected to a power source terminal, and the fifth and sixth diffusion regions are connected to an input/output pad.

6. The LVTSCR as set forth in claim 1, further comprising:
a first resistor having one terminal connected to the first diffusion region and the other terminal connected to the second diffusion region; and
a second resistor having one terminal connected to the fifth diffusion region and the other terminal connected to the sixth diffusion region.

7. A low voltage triggered silicon controlled rectifier (LVTSCR), comprising:
a first-type semiconductor substrate;
a second-type well formed in a predetermined region of the semiconductor substrate;
first and second diffusion regions formed in the well;
a third diffusion region formed in both the well and the substrate crossing the boundary between the well and the substrate;
fourth, fifth, and sixth diffusion regions sequentially formed in the substrate outside the well and adjacent to the third diffusion resion; and
a capacitor having a first terminal connected to the third diffusion region and a second terminal connected to the fourth diffusion region.

8. The LVTSCR as set forth in claim 7, wherein the first-type semiconductor substrate and the second, fourth and sixth diffusion regions are doped with P-type impurities, and the second-type well and the first, third and fifth diffusion regions are doped with N-type impurities.

9. The LVTSCR as set forth in claim 7, wherein the first and second diffusion region are connected to a power source terminal, and the fifth and sixth diffusion regions are connected to a ground terminal.

10. The LVTSCR as set forth in claim 7, wherein the first and second diffusion regions are connected to an input/output pad, and the fifth and sixth diffusion regions are connected to a ground terminal.

11. The LVTSCR as set forth in claim 7, wherein the first and second diffusion regions are connected to a power source terminal, and the fifth and sixth diffusion regions are connected to an input/output pad.

12. The LVTSCR as set forth in claim 7, further comprising:
a first resistor having one terminal connected to the first diffusion region and the other terminal connected to the second diffusion region; and
a second resistor having one terminal connected to the fifth diffusion region and the other terminal connected to the sixth diffusion region.
